(19) United States
(12) Patent Application Publication
(10) Pub. No.: US 2016/0343630 A1
(43) Pub. Date: Nov. 24, 2016

(54) SEMICONDUCTOR DEVICE AND MANUFACTURING METHOD OF THE SAME

(71) Applicant: Toyota Jidosha Kabushiki Kaisha, Toyota-shi, Aichi-ken (JP)

(72) Inventors: Takuya KADOGUCHI, Toyota-shi (JP); Takahiro HIRANO, Toyota-shi (JP); Masayoshi NISHIHATA, Nagoya-shi (JP); Keita FUKUTANI, Anjo-shi (JP); Tomomi OKUMURA, Anjo-shi (JP)

(73) Assignee: TOYOTA JIDOSHA KABUSHIKI KAISHA, Toyota-shi, Aichi-ken (JP)

(21) Appl. No.: 15/108,062

(22) PCT Filed: Dec. 18, 2014
(86) PCT No.: PCT/IB2014/002827

§ 371 Date: Jun. 24, 2016

(30) Foreign Application Priority Data
Dec. 26, 2013 (JP) 2013-269947

(51) Int. Cl. H01L 23/26; H01L 21/56; H01L 21/48; H01L 23/31; H01L 23/495

(52) U.S. Cl. CPC H01L 23/26; H01L 23/3114; H01L 23/49568; H01L 23/49562; H01L 23/4952; H01L 21/4825; H01L 21/4882; H01L 21/565

(57) ABSTRACT

A semiconductor device includes a metal member, a semiconductor element, a resin part, a primer layer, and a peel-off restraining part. The metal member has a surface that includes a semiconductor element mounting region and a resin close contact region that extends from the semiconductor element mounting region to an outer peripheral edge of the metal member. The semiconductor element is mounted on the semiconductor element mounting region. The resin part extends to a position outside a side surface of the metal member, and closely contacts with the resin close contact region, and collectively covers the semiconductor element and the metal member. The primer layer is disposed between the resin close contact region and the resin part. The peel-off restraining part is configured to restrain the metal member and the resin part from peeling from each other in the outer peripheral part of the resin close contact region.

### BACKGROUND OF THE INVENTION

1. Field of the Invention

The present invention relates to a semiconductor device and a manufacturing method of the same.

2. Description of Related Art

There has been known a semiconductor device that includes a semiconductor element and a pair of heatsinks for radiating heat from both surfaces of the semiconductor element and is configured such that the device is almost entirely covered with a molded resin. The semiconductor device includes a solder layer that joins the semiconductor element and the heatsinks, and a polyamide resin that is coated on a surface that contacts with the resin in a surface of the heatsinks and the like and improves adhesiveness with the resin. In the semiconductor device, a coating thickness of the polyamide resin is defined to approximately 20% or less of a dimension of a thickness of the solder layer (see Japanese Patent Application Publication No. 2003-124406 (JP 2003-124406 A), for example).

According to the configuration described in JP 2003-124406 A above, when the adhesiveness between the heatsinks and a molded resin around the semiconductor element is improved by reducing the coating thickness of the polyamide resin around the semiconductor element, the molded resin is prevented from peeling when thermal stress is acted.

Now, the molded resin part swells due to moisture absorption after being molded. During the swelling, a tensile stress is generated in a direction vertical to a surface of a metal member in an outer peripheral part of the metal member such as the heatsink, and, peeling of the resin part can be caused in the outer peripheral part of the metal member. Further, since a film thickness of a primer such as the polyamide resin becomes thin in the outer peripheral part of the metal member, adhesive strength decreases and the resin part tends to be peeled. The peeling of the resin part in the outer peripheral part of such a metal member can produce degradation of a withstand voltage, a degradation of insulation property of the semiconductor element and the like due to intrusion of a foreign matter into a mounting area of the semiconductor element when a crack is generated in a side part of the resin part.

### SUMMARY OF THE INVENTION

The present invention provides a semiconductor device that can restrain a resin part in an outer peripheral part of a metal plate from being peeled and a manufacturing method of the same.

A semiconductor device according to a first aspect of the present invention includes a metal member, a semiconductor element, a resin part, a primer layer, and a peel-off restraining part. The metal member has a surface that includes a semiconductor element mounting region and a resin close contact region, the resin close contact region extending from the semiconductor element mounting region to an outer peripheral edge of the metal member. The semiconductor element is mounted on the semiconductor element mounting region. The resin part extends to a position outside a side surface of the metal member, closely contacts with the resin close contact region, and collectively covers the semiconductor element and the metal member. The primer layer is disposed between the resin close contact region and the resin part. The peel-off restraining part is configured to suppress the metal member and the resin part from peeling, due to moisture absorption of the resin part, from each other in the outer peripheral part of the resin close contact region.

A semiconductor device according to a second aspect of the present invention includes a metal member, a semiconductor element, a resin part, and a primer layer. The metal member has a surface that includes a semiconductor element mounting region and a resin close contact region, the resin close contact region extending from the semiconductor element mounting region to an outer peripheral edge of the metal member. The semiconductor element is mounted on the semiconductor element mounting region. The resin part has moisture absorbency, extends to a position outside a side surface of the metal member, closely contacts with the resin close contact region, and collectively covers the semiconductor element and the metal member. The primer layer is disposed between the resin close contact region and the resin part. Further, a peel-off restraining part configured to restrain the metal member and the resin part from peeling from each other in an outer peripheral part of the resin close contact region is provided to at least one of the metal member and the resin part.

According to the semiconductor devices of the first and second aspects of the present invention, the resin part in the outer peripheral part of the metal member can be restrained from being peeled.

A manufacturing method of a semiconductor device according to a third aspect of the present invention includes: performing a plating treatment on a lead frame raw material; forming the lead frame raw material that has a side surface exposed from a plating layer by performing a press working on the plated lead frame raw material; mounting a semiconductor element on a surface of the press-worked lead frame raw material; coating a primer on a surface and a side surface of the lead frame raw material on which the semiconductor element is mounted; and collectively sealing the lead frame raw material and the semiconductor element with a resin by molding the resin after the coating of the primer so as to bring the resin into close contact with the surface and the side surface of the lead frame raw material.

According to the manufacturing method of the third aspect of the present invention, the resin part in the outer peripheral part of the metal member can be restrained from being peeled.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a top view that shows a semiconductor device according to an embodiment (first embodiment) of the present invention;

FIG. 2 is a drawing obtained by omitting a resin part in the semiconductor device of FIG. 1;

FIG. 3 is a cross-sectional view taken along a line of FIG. 1;

FIG. 4 is a cross-sectional view taken along a IV-IV line of FIG. 1;

FIG. 5 is an enlarged view of an X part of FIG. 3;

FIG. 6 is a drawing that shows an analysis result of a vertical stress that acts on an interface between a resin close contact region 540a and a resin part 66 during swelling due to moisture absorption of the resin part 66;

FIG. 7 is a drawing that shows a relationship between a thickness and a tensile strength of a primer layer;

FIG. 8 is a cross-sectional view that shows a peel-off restraining part according to the embodiment (Embodiment 1);

Each of FIG. 9A and FIG. 9B is a cross-sectional view that shows an effect of a groove part 100;

FIG. 10A to FIG. 10D are drawings that show variations of a cross-sectional shapes of the groove part 100;

FIG. 11A to FIG. 11D are drawings that show an embodiment of a manufacturing method of a semiconductor device 10A that includes the peel-off restraining part according to Embodiment 1;

FIG. 12 is a cross-sectional view that shows the peel-off restraining part according to another embodiment (Embodiment 2) of the present invention;

FIG. 13 is a cross-sectional view that shows the peel-off restraining part according to a variant embodiment to the Embodiment 2;

FIG. 14 is a cross-sectional view that shows the peel-off restraining part according to another embodiment (Embodiment 3) of the present invention;

FIG. 15A to FIG. 15D are drawings that show an embodiment of a manufacturing method of a semiconductor device 10B that includes the peel-off restraining part according to Embodiment 3;

FIG. 16 is a cross-sectional view that shows the peel-off restraining part according to another embodiment (Embodiment 4) of the present invention; and

FIG. 17A to FIG. 17D are drawings that show an embodiment of a manufacturing method of a semiconductor device 10C that includes the peel-off restraining part according to the Embodiment 4.

### DETAILED DESCRIPTION OF EMBODIMENTS

Hereinafter, the respective embodiments will be described with reference to accompanying drawings.

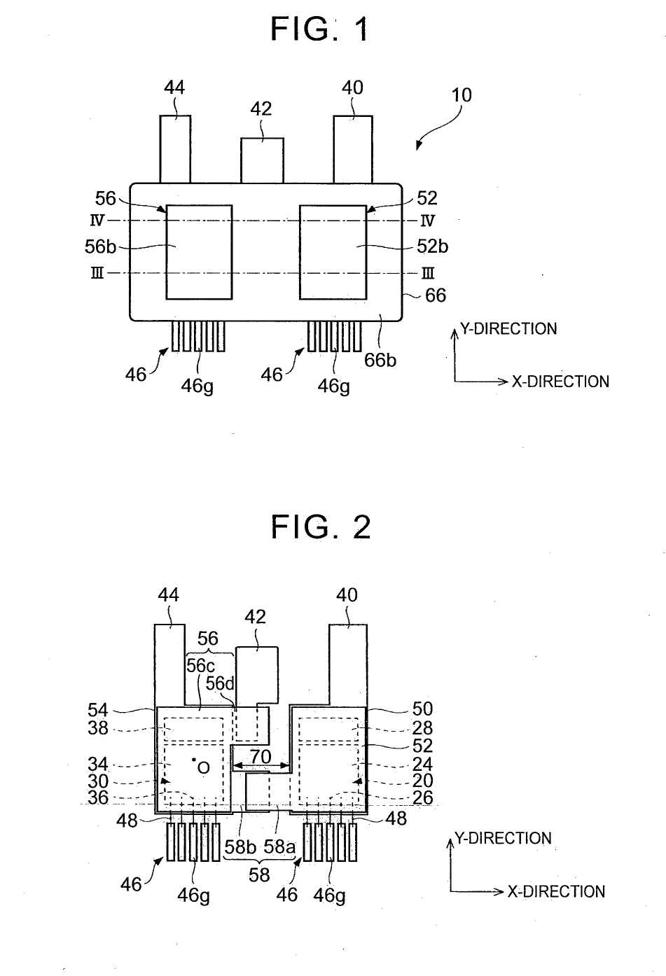

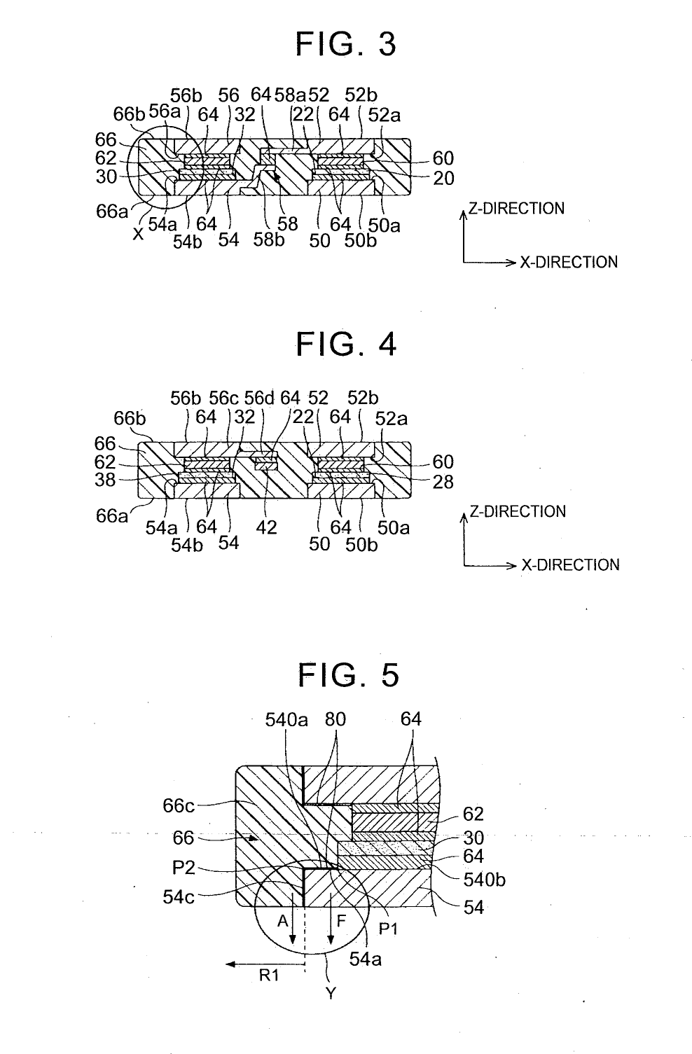

FIG. 1 is a top view that shows a semiconductor device 10 according to an embodiment (first embodiment). FIG. 2 is a drawing obtained by omitting a resin part in the semiconductor device of FIG. 1. FIG. 3 is a cross-sectional view taken along a line of FIG. 1. FIG. 4 is a cross-sectional view taken along a IV-IV line of FIG. 1. In FIG. 3 and FIG. 4, a primer layer 80 and a peel-off restraining part, which are described below are omitted from showing.

The semiconductor device 10 is typically used in a power converter such as an inverter and a converter for driving a running motor in a hybrid vehicle or an electric vehicle. However, the semiconductor device 10 may be used in other applications in a vehicle (for example, for an electric steering device) or may be used in applications other than for a vehicle (for example, a power device of other electrically-driven device or the like).

In the following description, for convenience sake, a direction of a thickness of an IGBT element (Insulated Gate Bipolar Transistor) is taken as a Z-direction. Further, a direction that is orthogonal to the Z-direction and in which two IGBT elements that constitute upper and lower arms are arranged in parallel is taken as an X-direction. Still further, a direction orthogonal to both the X-direction and the Z-direction is taken as a Y-direction. Further, in the following description, for the convenience sake, although the Z-direction corresponds to a vertical direction and a side in which a first terminal 60 is present with respect to a first heatsink 50 is taken as “an upper side”, a mounting direction of the semiconductor device 10 is arbitrary.

The semiconductor device 10 includes the IGBT elements 20 and 30, FWD (Free Wheel Diode) elements 28 and 38, a high-potential power terminal 40, a low potential power terminal 42, an output terminal 44, and, a control terminal 46 that includes a gate terminal 46g. Further, the semiconductor device 10 includes four heatsinks 50, 52, 54 and 56, a contact part 58, two terminals 60 and 62, a solder 64, and a resin part 66 as shown in FIG. 1 to FIG. 4.

The IGBT element 20 and the FWD element 28 form an upper arm of upper and lower arms, and the IGBT element 30 and the FWD element 38 form a lower arm of the upper and lower arms.

The IGBT element 20 includes a collector electrode 22 on a lower surface side and an emitter electrode 24 and a gate electrode 26 on an upper surface side as shown in FIG. 2 and FIG. 3.

A first heatsink 50 is disposed on a lower surface side of the IGBT element 20. The collector electrode 22 is electrically and mechanically connected with a surface 50a on an upper side of the first heatsink 50 via the solder 64. In an embodiment shown in FIG. 2, also a cathode electrode of the FWD element 28 is connected with the surface 50a on the upper side of the first heatsink 50.

As shown in FIG. 2, the first heatsink 50 is a substantially rectangular metal plate and has a high-potential power terminal 40 that extends from one side of the rectangle shape of the first heatsink 50 in the Y-direction. The first heatsink 50 may be formed from a single heteromorphous lead frame together with the high-potential power terminal 40 and the like. Alternatively, the high-potential power terminal 40 may be formed into a separate body from the first heatsink 50 and attached to the first heatsink 50. The high-potential power terminal 40 is electrically connected with the IGBT element 20 and FWD element 28 via the first heatsink 50. A part of the high-potential power terminal 40 is externally protruding from a side surface of the resin part 66 (a side surface having the Y-direction as a normal line) as shown in FIG. 1.

A surface 50b on a lower side of the first heatsink 50 is exposed from a surface 66a on a lower side of the resin part 66 as shown in FIG. 3 and FIG. 4. Thus, heat generated by the IGBT element 20 and the FWD element 28 can be externally radiated from the surface 50b of the first heatsink 50. In the embodiment shown in FIG. 3, the surface 50b on the lower side of the first heatsink 50 is flush with the surface 66a on the lower side of the resin part 66 but may be offset in the Z-direction.

The first terminal 60 is disposed on an upper surface side of the IGBT element 20 such that the first terminal 60 does not overlap with the gate electrode 26 but faces the emitter electrode 24 in the Z-direction. The first terminal 60 is a flat metal plate (a metal block) but may have a bent part. A surface on a lower side of the first terminal 60 is electrically and mechanically connected with the emitter electrode 24 via the solder 64. Also the anode electrode of the FWD element 28 is connected with the surface on the lower side of the first terminal 60. The first terminal 60 has a relay function for electrically connecting the IGBT element 20 and FWD element 28 with the second heatsink 52 and a function for securing a height for performing a wire bonding on the gate electrode 26.

The gate electrode 26 is connected with the gate terminal 46g of the control terminal 46 according to the upper arm via a bonding wire 48. The control terminal 46 according to the upper arm may be formed of the single heteromorphous lead frame together with the first heatsink 50, the high-potential power terminal and the like. The control terminal 46 according to the upper arm may include, in addition to the gate terminal 46g, a terminal that is connected with a temperature measurement diode, a sense emitter or the like. The control terminal 46 according to the upper arm is externally protruding from a side surface (a side surface having the Y-direction as the normal line) on an opposite side from a protruding side of the high-potential power terminal 40 in the resin part 66 as shown in FIG. 1 and FIG. 2.

The second heatsink 52 is disposed on a surface on an upper side of the first terminal 60. A surface 52a on a lower side of the second heatsink 52 is electrically and mechanically connected with the surface on the upper side of the first terminal 60 via the solder 64. Thus, the second heatsink 52 is electrically connected with the emitter electrode 24 of the IGBT element 20 and the anode electrode of the FWD element 28 via the first terminal 60.

The second heatsink 52 is a substantially rectangular metal plate and is disposed such that a large part of the second heatsink 52 overlaps with the first heatsink 50 from a top view (a downward view in the Z-direction). The second heatsink 52 has a substantially same rectangular shape as that of an external shape of the first heatsink 50 as shown in FIG. 2. A surface 52b on an upper side of the second heatsink 52 is exposed from a surface 66b on an upper side of the resin part 66. Thus, heat generated by the IGBT element 20 and the FWD element 28 can be externally radiated from the surface 52b of the second heatsink 52 via the first terminal 60. In the embodiment shown in FIG. 3 and FIG. 4, the surface 52b on the upper side of the second heatsink 52 is flush with the surface 66b on the upper side of the resin part 66 but may be offset in the Z-direction.

A first contact part 58a that is an element of the contact part 58 is integrally provided to the second heatsink 52. However, the first contact part 58a may be formed in a separate body from the second heatsink 52 and attached to the second heatsink 52. The first contact part 58a extends in the X-direction toward the IGBT element 30.

The IGBT element 30 includes a collector electrode 32 on a lower surface side and an emitter electrode 34 and a gate electrode 36 on an upper surface side as shown in FIG. 2 and FIG. 3. The IGBT element 30 is disposed in parallel with the IGBT element 20 in the X-direction. In the embodiment shown in FIG. 3, the IGBT element 30 is disposed in a relationship in which the IGBT element 30 is not offset with respect to the IGBT element 20 in the Y-direction. However, the IGBT element 30 may be offset in the Y-direction.

The third heatsink 54 is disposed on a lower surface side of the IGBT element 30. The collector electrode 32 is electrically and mechanically connected with an upper surface 54a of the third heatsink 54 via the solder 64. In the embodiment shown in FIG. 2, also the cathode electrode of the FWD element 38 is connected with the upper surface 54a of the third heatsink 54.

As shown in FIG. 2, the third heatsink 54 is a substantially rectangular metal plate and has the output terminal 44 that extends from one side of the rectangle shape of the third heatsink 54 in the Y-direction. The third heatsink 54 may be formed from a single heteromorphous lead frame together with the output terminal 44 and the like. Alternatively, the output terminal 44 may be formed into a separate body from the third heatsink 54 and attached to the third heatsink 54. The output terminal 44 is electrically connected with the IGBT element 30 and FWD element 38 via the third heatsink 54. A part of the output terminal 44 is externally protruding from the side surface of the resin part 66 (a side surface having the Y-direction as a normal line) as shown in FIG. 2. The side surface of the resin part 66 from which the output terminal 44 is protruding is the same as the side surface of the resin part 66 from which the high-potential power terminal 40 is protruding.

The surface 54b on the lower side of the third heatsink 54 is exposed from the surface 66a on the lower side of the resin part 66 as shown in FIG. 3 and FIG. 4. Thus, heat generated by the IGBT element 30 and the FWD element 38 can be externally radiated from the surface 54b of the third heatsink 54. In the embodiment shown in FIG. 3 and FIG. 4, the surface 54b on the lower side of the third heatsink 54 is flush with the surface 66a on the lower side of the resin part 66 but may be offset in the Z-direction.

A second contact part 58b that is an element of the contact part 58 is integrally provided to the third heatsink 54. However, the second contact part 58b may be separately formed from the third heatsink 54 and attached to the third heatsink 54. In the embodiment shown in FIG. 3, the second contact part 58b extends, in an upper direction, toward the surface 56a on the lower side of the fourth heatsink 56 and extends in the X-direction, toward the IGBT element 20 side. The second contact part 58b is electrically and mechanically connected with the first contact part 58a via the solder 64 as shown in FIG. 3. The second contact part 58b and the first contact part 58a are formed between the second heatsink 52 and the third heatsink 54 in the X-direction and electrically and mechanically, and mutually connected between the second heatsink 52 and the third heatsink 54 in the X-direction.

The second terminal 62 is disposed on an upper surface side of the IGBT element 30 such that the second terminal 62 does not overlap with the gate electrode 36 but faces the emitter electrode 34 in the Z-direction. The second terminal 62 is a flat metal plate (metal block) but may have a bent part. A surface on a lower side of the second terminal 62 is electrically and mechanically connected with the emitter electrode 34 via the solder 64. Also the anode electrode of the FWD element 38 is connected with the surface on the lower side of the second terminal 62.

The second terminal 62 has a relay function for electrically connecting the IGBT element 30 and FWD element 38 with the fourth heatsink 56 and a function for securing a height for performing the wire bonding on the gate electrode 36.

The gate electrode 36 is connected with the gate terminal 46g of the control terminal 46 according to the lower arm via the bonding wire 48. The control terminal 46 according to the lower arm may be formed of the single heteromorphous lead frame together with the third heatsink 54, the output terminal 44 and the like. The control terminal 46 according to the lower arm may include, in addition to the gate terminal 46g, a terminal that is connected with a temperature measurement diode, a sense emitter or the like. The control terminal 46 according to the lower arm is externally protruding from a side surface (a side surface having the Y-direction as the normal line) on an opposite side from a drawing side of the high-potential power terminal 40 in the resin part 66 as shown in FIG. 1 and FIG. 2.

The fourth heatsink 56 is disposed on a surface of an upper side of the second terminal 62. A surface 56a on a lower side of the fourth heatsink 56 is electrically and mechanically connected with a surface on an upper side of the second terminal 62 via the solder 64. Thus, the fourth heatsink 56 is electrically connected with the emitter electrode 34 of the IGBT element 30 and the anode electrode of the FWD element 38 via the second terminal 62.

The fourth heatsink 56 is a substantially rectangular metal plate and is disposed such that a large part of the fourth heatsink 56 overlaps with the third heatsink 54 from a top view (a downward view in the Z-direction). As shown in FIG. 2, the fourth heatsink 56 has the substantially same rectangular shape as an external shape of the third heatsink 54. A surface 56b on an upper side of the fourth heatsink 56 is exposed from the surface 66b on the upper side of the resin part 66. Thus, heat generated by the IGBT element 30 and the FWD element 38 can be externally radiated from the surface 56b of the fourth heatsink 56 via the second terminal 62. In the embodiment shown in FIG. 3 and FIG. 4, the surface 56b on the upper side of the fourth heatsink 56 is flush with the surface 66b on the upper side of the resin part 66 but may be offset in the Z-direction.

The fourth heatsink 56 includes a body part 56c that defines surfaces 56a and 56b and an extension part 56d that extends from a side surface of the body part 56c to the IGBT element 20 side in the X-direction. The extension part 56d can be integrally formed with the body part 56c. However, the extension part 56d may be formed into a separate body from the body part 56c and attached to the body part 56c.

The extension part 56d is formed between the body part 56c of the fourth heatsink 56 and the second heatsink 52 (the body part excluding the first contact part 58a) in the X-direction in the same manner as the contact part 58. However, the extension part 56d is offset with respect to the contact part 58 in the Y-direction so as not to overlap with the contact part 58 in the Z-direction.

The low potential power terminal 42 is electrically connected with the fourth heatsink 56. Specifically, the low potential power terminal 42 is electrically and mechanically connected with the extension part 56d of the fourth heatsink 56 via the solder 64 as shown in FIG. 4. The low potential power terminal 42 may be formed of a single heteromorphous lead frame together with the third heatsink 54, the output terminal 44, the control terminal 46 according to the lower arm and the like. A part of the low potential power terminal 42 is externally protruding from the side surface of the resin part 66 (a side surface having the Y-direction as a normal line) as shown in FIG. 2. The side surface of the resin part 66 from which the low potential power terminal 42 is protruding is the same surface as that of the resin part 66 from which the high-potential power terminal 40 and the output terminal 44 are protruding.

The low potential power terminal 42 is disposed in a region 70 between the body part 56c of the fourth heatsink 56 and the second heatsink 52 (the body part excluding the first contact part 58a) in the X-direction, that is, in the region 70 in which the extension part 56d is disposed. Thus, the high-potential power terminal 40, the low potential power terminal 42 and the output terminal 44 are disposed in a positional relationship in which the low potential power terminal 42 is located between the output terminal 44 and the high-potential power terminal 40 in the X-direction as shown in FIG. 2. In the embodiment shown in the drawing, an entirety of the low potential power terminal 42 is disposed in a region between the body part 56c of the fourth heatsink 56 and the second heatsink 52 (the body part excluding the first contact part 58a).

The resin part 66 collectively seals the IGBT elements 20 and 30, the FWD elements 28 and 38, a part of the high-potential power terminal 40, a part of the low potential power terminal 42, a part of the output terminal 44, a part of the control terminal 46, a part excluding the surfaces 50b, 52b, 54b, and 56b in the respective heatsinks 50, 52, 54 and 56, the contact part 58, and the respective terminals 60 and 62. In the embodiment shown in the drawing, the resin part 66 is formed into an external form of a substantial cuboid. As described above, the high-potential power terminal 40, the low potential power terminal 42, and the output terminal 44 are protruding in the Y-direction from the side surface of the resin part 66 as shown in FIG. 2. Protruding positions of the high-potential power terminal 40, the low potential power terminal 42 and the output terminal 44 in the side surface of the resin part 66 may be an arbitrary position in the Z-direction, for example, a vicinity of a center in the Z-direction in the side surface of the resin part 66.

In each of the heatsinks 50, 52, 54 and 56, the primer layer 80 (see FIG. 5) is formed to improve the adhesiveness between the resin part 66 and each of the respective heatsinks 50, 52, 54 and 56. The primer layer 80 is formed of, for example, a polyamide film. The primer layer 80 may be formed of other material such as polyamide-imide, polyimide or epoxy. The primer layer 80 may be coated by an arbitrary coating method (dipping, spin, dispense or the like). In order to improve the adhesiveness of the primer layer 80 to the respective heatsinks 50, 52, 54 and 56, a plating treatment such as nickel plating or gold plating is applied to the respective heatsinks 50, 52, 54 and 56.

The semiconductor device 10 configured like this is a so-called 2-in-1 package that collectively includes two IGBT elements 20 and 30 that form the upper and lower arms (including in the single resin part 66). Further, the heatsinks 50, 52, 54 and 56 are disposed on both sides of each of the IGBT elements 20 and 30 in the Z-direction, and the heat from the IGBT elements 20 and 30 can be radiated from the both sides in the Z direction thereby, that is, this configuration is excellent in a heat radiation property. However, the semiconductor device 10 may not be the 2-in-1 package, may have a configuration that includes one IGBT element 20 or 30, or may be a so-called 6 in 1 package that collectively includes (includes in a single resin part 66) the IGBT elements 20 and 30 of the respective upper and lower arms of three-phases (U-phase, V-phase, and W-phase).

Further, the high-potential power terminal 40 and the low potential power terminal 42 are disposed adjacently in the X-direction (without interposing the output terminal 44 therebetween). Therefore, a distance between the high-potential power terminal 40 and the low potential power terminal 42 in the X-direction can be shortened compared with a configuration in which the output terminal 44 is disposed between the high-potential power terminal 40 and the low potential power terminal 42 in the X-direction. Thus, a surge voltage that is generated during switching of the IGBT elements 20 and 30 can be reduced. However, the number, kind, an alignment manner and the like of respective terminals 40, 42 and 44 that extend exposed from the resin part 66 are arbitrary. For example, a side of the resin part 66 from which the respective terminals 40, 42 and 44 are exposed may be arbitrarily selected.

The first heatsink 50, the third heatsink 54, the high-potential power terminal 40, the low potential power terminal 42, the output terminal 44 and the control terminal 46 according to the upper and lower arms can be formed from a single heteromorphous lead frame as described below. Thus, a configuration excellent in the productivity can be achieved. However, manufacturing methods of these constituent elements are arbitrary.

The semiconductor device 10 according to the present embodiment includes the peel-off restraining part that restrains the respective heatsinks 50, 52, 54 and 56 and the resin part 66 from peeling, due to moisture absorption of the resin part 66, from each other in an outer peripheral part of surfaces of the respective heatsinks 50, 52, 54 and 56. Hereinafter, the peel-off restraining part will be described in more detail. Hereinafter, as a typical example, the peel-off restraining part that restrains the third heatsink 54 and the resin part 66 from peeling from each other will be described. The peel-off restraining part may be provided to each of the heatsinks 50, 52, 54 and 56 or may be provided to any one, two or three of the heatsinks 50, 52, 54 and 56. In FIG. 1 to FIG. 4, the peel-off restraining part is omitted from showing in the drawing.

In the following description, an “inside” and an “outside” are used, for convenience sake, with a center 0 (see FIG. 2) of the third heatsink 54 as a reference in a top view. That is, the “inside” is a side close to the center 0 of the third heatsink 54, and the “outside” is a side far from the center 0 of the third heatsink 54.

Here, firstly, prior to the description of the peel-off restraining part, a principle of the peeling due to the moisture absorption of the resin part 66 will be described.

FIG. 5 is an enlarged view of an X part in FIG. 3. In FIG. 5, from the convenience of describing the principle of the peeling, the peel-off restraining part is omitted from showing in the drawing. Hereinafter, a configuration that is not provided with the peel-off restraining part (the configuration such as shown in FIG. 5) is taken as a reference embodiment.

As described above, the resin part 66 is in close contact with the surface 54a of the third heatsink 54, the IGBT element 30, the FWD element 38, and the like. For example, the surface 54a of the third heatsink 54 is in close contact with the region 540a excluding a joining region (a part with which the solder 64 contacts) 540b between the IGBT element 30 and the FWD element 38. The joining region 540b corresponds to an element mounting region on which the IGBT element 30 and the FWD element 38 are mounted. The region 540a is formed around the joining region 540b and extends from the joining region 540b to an outer peripheral part in the surface 54a. Hereinafter, the region 540a will be referred to as a “resin close contact region 540a”. The resin part 66 is in close contact with the side surface 54c of the third heatsink 54 in some cases depending on embodiments as described below and is not intentionally in close contact (or adhesive strength is reduced) in some cases.

As described above, the primer layer 80 is formed on the third heatsink 54 in order to improve the adhesiveness between the resin part 66 and the third heatsink 54. The primer layer 80 is formed at least in the resin close contact region 540a.

The resin part 66 absorbs atmospheric moisture after being molded and expands (swells). When an area 66c (hereinafter, referred to as “a heatsink-surrounding part 66c”) on an outer side of the third heatsink 54 in the resin part 66 (see an arrow mark R1 of FIG. 5) expands, a tensile stress is imparted to the joining surface between the resin close contact region 540a and the resin part 66. For example, while the heatsink-surrounding part 66c of the resin part 66 expands in an arrow mark A direction of FIG. 5 during moisture absorption, a downward load F is imparted to the third heatsink 54 via a close contact part between the heatsink-surrounding part 66c of the resin part 66 and the side surface 54c of the third heatsink 54. Thus, the outer peripheral part of the third heatsink 54 tends to deform downward, and the tensile stress is generated in the joining surface between the resin close contact region 540a and the resin part 66. As a result, in the outer peripheral part of the third heatsink 54, the adhesive strength between the surface 54a of the third heatsink 54 and the resin part 66 is decreased and the peeling tends to occur.

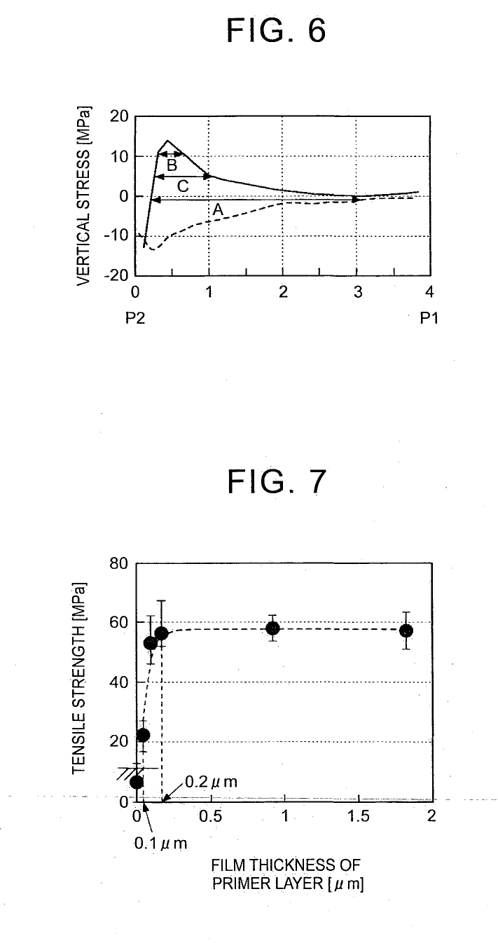

FIG. 6 is a drawing that shows an analysis result of a vertical stress that acts on an interface between a resin close contact region 540a and a resin part 66 during expansion due to moisture absorption of the resin part 66. The analysis result of FIG. 6 relates to a reference embodiment that does not include the peel-off restraining part. In FIG. 6, the vertical stress is shown in a vertical axis, a lower side of 0 shows a compression direction, and an upper side shows a tensile direction. A horizontal axis shows the respective positions of the resin close contact region 540a from an element end P1 to an outer peripheral edge P2. In FIG. 6, a dashed line shows a state before the moisture absorption and a solid line shows a state after the moisture absorption.

The state before the moisture absorption (for example, a state immediately after the molding) is a state high in the adhesive strength because, as shown with the dashed line in FIG. 6, a compressive stress acts between the surface 54a of the third heatsink 54 and the resin part 66. On the other hand, during the expansion due to the moisture absorption of the resin part 66, as shown with the solid line in FIG. 6, a vertical stress is generated in a tensile direction between the surface 54a of the third heatsink 54 and the resin part 66 in the outer peripheral part of the third heatsink 54. This is because, as described above, the downward load F (see FIG. 5) acts on the outer peripheral part of the third heatsink 54 due to the expansion of the heatsink-surrounding part 66c of the resin part 66.

FIG. 7 is a drawing that shows a relationship between a thickness of the primer layer 80 and the tensile strength. In FIG. 7, the tensile strength is shown in a vertical axis and the thickness of the primer layer 80 is shown in a horizontal axis. The thickness of the primer layer 80 is a thickness in a cross-section when the primer layer 80 is cut with a surface vertical to the surface 54a of the third heatsink 54.

The tensile strength exceeds 15 MPa to the thickness of the primer layer 80 of 0.1 μm or more and stabilizes in the vicinity of 60 MPa to the thickness of the primer layer 80 of 0.2 μm or more as shown in FIG. 7.

While the primer layer 80 becomes thicker around the IGBT element 30 and the FWD element 38 under an influence of surface tension, it becomes thinner in the outer peripheral part of the third heatsink 54. This is a phenomenon generated irrespective of the coating method of the primer layer 80. For example, in some coating embodiments, while the thickness of the primer layer 80 is 0.6 μm at an element end P1, the thickness is 0.05 μm at the outer peripheral edge P2. This means that the tensile strength of the primer layer 80 decreases relatively in the outer peripheral part of the third heatsink 54. This becomes a factor that induces the peeling of the resin part 66 from the resin close contact region 540a in the outer peripheral part of the third heatsink 54 coupled with the generation of the tensile stress in the outer peripheral part of the third heatsink 54 described above.

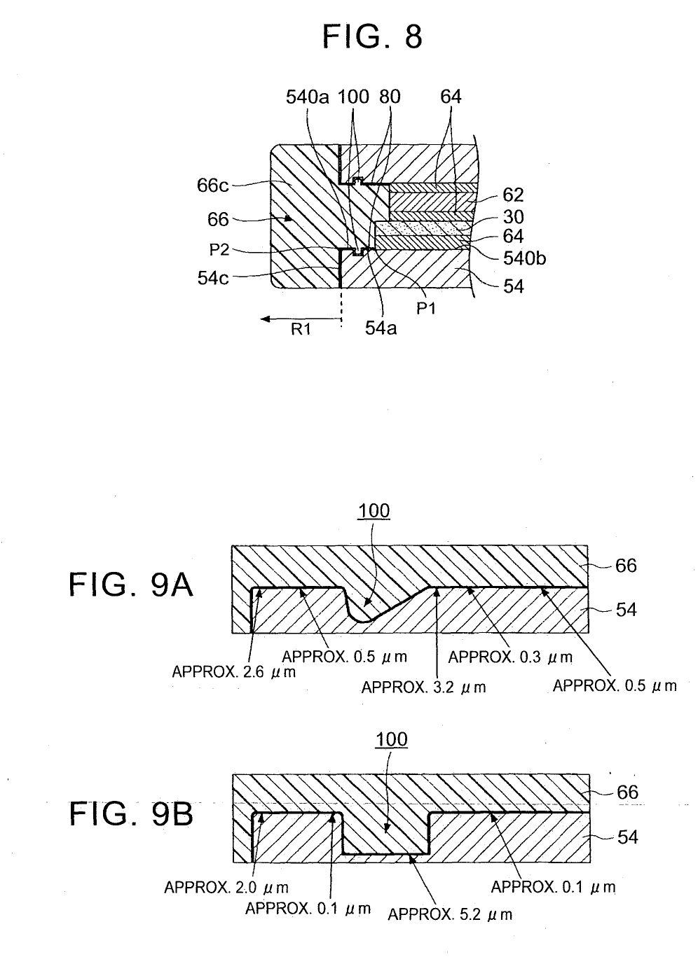

FIG. 8 is a cross-sectional view that shows a peel-off restraining part according to an embodiment (Embodiment 1) of the present invention.

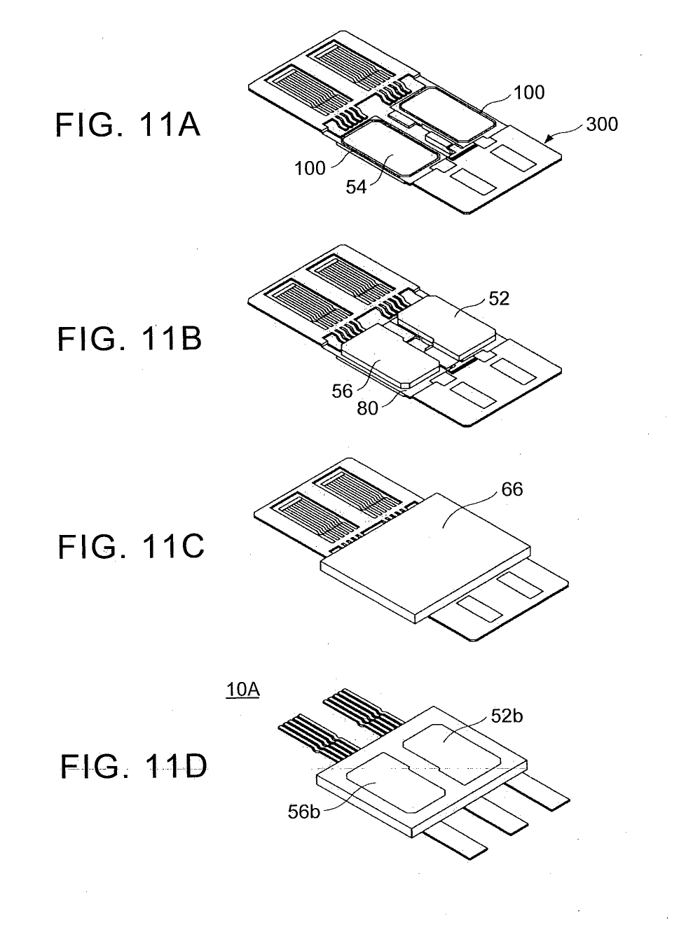

The peel-off restraining part of the present embodiment is achieved by a groove part 100 formed in the resin close contact region 540a of the third heatsink 54. The groove part 100 is preferably formed over an entire circumference in the outer peripheral part of the resin close contact region 540a of the third heatsink 54 (see FIG. 11) but may be formed only partially not over the entire circumference. Since the groove part 100 becomes a liquid reservoir of the primer during primer coating, the primer is prevented from being drawn from the outer peripheral part of the third heatsink 54 to an inner side thereof (IGBT element 30 side) under influence of surface tension. A depth of the groove part 100 is arbitrary but may be approximately 0.3 mm, for example.

The groove part 100 is formed in a region of 3 mm or less to an inner side from the outer peripheral edge P2 of the surface 54a of the third heatsink 54, preferably formed in a region between 0.3 mm to 1.2 mm to the inner side from the outer peripheral edge P2, and is most preferably formed in a region between 0.4 mm to 0.8 mm to the inner side from the outer peripheral edge P2. This is because when the groove part 100 is not present, the tensile stress is generated in a region (see A of FIG. 6) of 3 mm or less to the inner side from the outer peripheral edge P2 of the surface 54a of the third heatsink 54 as shown in FIG. 6. Further, when the groove part 100 is not present, the tensile stress of 5 MPa or more is generated in a region (see C of FIG. 6) between 0.3 mm to 1.2 mm to the inner side from the outer peripheral edge P2 as shown in FIG. 6. Further, when the groove part 100 is not present, the tensile stress of 10 MPa or more is generated as shown in FIG. 6 in a region (see B of FIG. 6) between 0.4 mm to 0.8 mm to the inner side from the outer peripheral edge P2. When the groove part 100 is formed in a range in which such tensile stress is generated, the thicknesses of the primer layer 80 in such a range and in a range to the outer peripheral edge P2 can be effectively increased.

A distance from the outer peripheral edge P2 (for example, “0.3 mm” or the like regarding the region between 0.3 mm to 1.2 mm) may be a distance measured as a shortest distance from the outer peripheral edge P2 (when a shape of the surface 54a is a rectangle, a distance in a vertical direction to a side). Alternatively, it may be a distance measured along a direction in which a distance from the outer peripheral edge P2 to the IGBT element 30 that is a target is a shortest distance.

FIG. 9A and FIG. 9B are cross-sectional views that show an effect of the groove part 100 and drawings that show results of measurement of thicknesses of the primer layer 80 at a plurality of points in the resin close contact region 540a. FIG. 9A and FIG. 9B show embodiments of coating, in which the groove parts 100 having different cross-sectional shapes are used. However, since coating conditions are different, a difference of numerical values is not generated only by the cross-sectional shape of the groove part 100.

In the embodiment shown in FIG. 9A, by providing the groove part 100, the thickness of the primer layer 80 of approximately 0.5 μm can be secured also in the outer peripheral part of the third heatsink 54. When the thickness of the primer layer 80 of approximately 0.5 μm is secured, a high tensile strength can be imparted to the primer layer 80 also in the outer peripheral part of the third heatsink 54 as shown in FIG. 7, and the resin part 66 can be effectively restrained from being peeled from the resin close contact region 540a in the outer peripheral part of the third heatsink 54.

Further, in the embodiment shown in FIG. 9B, by forming the groove part 100, the thickness of the primer layer 80 of approximately 0.1 μm can be secured also in the outer peripheral part of the third heatsink 54. When the thickness of the primer layer 80 of approximately 0.1 μm is secured, as shown in FIG. 7, a high tensile strength (the tensile strength of 15 MPa or more) can be imparted to the primer layer 80 also in the outer peripheral part of the third heatsink 54, and the resin part 66 can be effectively restrained from being peeled from the resin close contact region 540a in the outer peripheral part of the third heatsink 54.

Here, when the thickness of the primer layer 80 in the outer peripheral part of the third heatsink 54 is at least 0.1 μm or more as shown in FIG. 7, the tensile strength of 15 MPa or more can be secured, and a maximum value of the tensile stress shown in FIG. 6 (less than 15 MPa) can be responded. However, the groove part 100 is preferably configured such that the thickness of the primer layer 80 in the outer peripheral part of the third heatsink 54 is to be 0.2 μm or more. This is because the tensile strength is stabilized in the vicinity of 60 MPa with respect to the thickness of the primer layer 80 of 0.2 μm or more as described above with reference to FIG. 7.

The thickness of the primer layer 80 in the groove part 100 becomes relatively large because the groove part 100 becomes the liquid reservoir. For example, in one coating embodiment, the thickness of the primer layer 80 in the groove part 100 having a depth of 3 mm became approximately 5 μm.

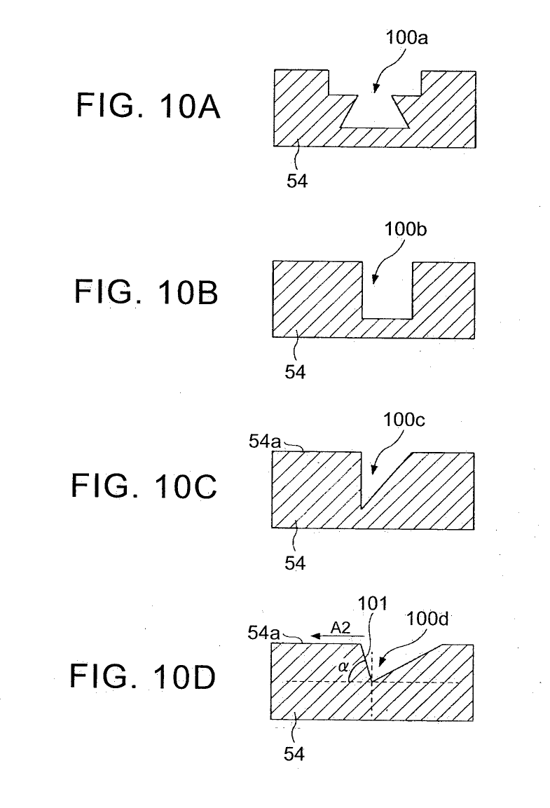

FIG. 10A to FIG. 10D are drawings that show variations of cross-sectional shape of the groove part 100. The cross-sectional shape of the groove part 100 is arbitrary but may be any one of the cross-sectional shapes such as the respective groove parts 100a, 100b, 100c and 100d shown in FIG. 10A to FIG. 10D, for example. The cross-sectional shape of the groove part 100a is made of a combination of a rectangular cross-section and a triangular cross-section, and an upper part (an apical part) of the triangular cross-section on a lower side overlaps with the rectangular cross-section. The cross-sectional shape of the groove part 100b is a rectangular cross-section, and the cross-sectional shape of the groove part 100c is a triangular cross-section in which a vertical wall on an outer side is vertical to the surface 54a. The cross-sectional shape of the groove part 100d is a triangular cross-section in which a vertical wall 101 on an outer side inclines with respect to the surface 54a in a direction in which an upper edge side of the vertical wall 101 is an outer side. In particular, in the case of the groove part 100d, an angle α between the vertical wall 101 of the groove part 100d and a surface in parallel with the surface 54a is preferably formed at 45° or more. Thus, a relative movement (see an arrow mark A2) in a shearing direction with respect to the third heatsink 54 of the resin part 66 is restrained during thermal shrinkage of the third heatsink 54, and the adhesive strength can be improved. For example, typically, since the third heatsink 54 has linear expansion coefficient larger than that of the resin part 66, the third heatsink 54 shrinks more than the resin part 66 after molding of the resin part 66, and the resin part 66 tends to move relatively in the direction of the arrow mark A2 with respect to the third heatsink 54. However, such a movement can be restrained by the vertical wall 101 of the groove part 100d.

FIG. 11A to FIG. 11D are drawings that show an embodiment of a manufacturing method of a semiconductor device 10A that includes the peel-off restraining part according to Embodiment 1.

Firstly, a lead frame (heteromorphous lead frame) 300 is prepared as shown in FIG. 11A. In the lead frame 300, the groove part 100 is formed by press working. In the embodiment shown in FIG. 11A, the groove part 100 is formed for each of the first heatsink 50 and the third heatsink 54.

Then, the IGBT elements 20 and 30, the FWD elements 28 and 38, the respective terminals 60 and 62, the second heatsink 52 and the fourth heatsink 56 are mounted on the lead frame 300 as shown in. FIG. 11B, and then the wire bonding is performed. Thereafter, also the primer is coated and the primer layer 80 is formed.

Next, the resin part 66 is formed by mold forming as shown in FIG. 11C.

Next, the respective upper parts of the resin part 66, the second heatsink 52, and the fourth heatsink 56 and the like are machined and superfluous areas in the lead frame 300 such as tie bars are cut as shown in FIG. 11D, thus, the semiconductor device 10A is completed.

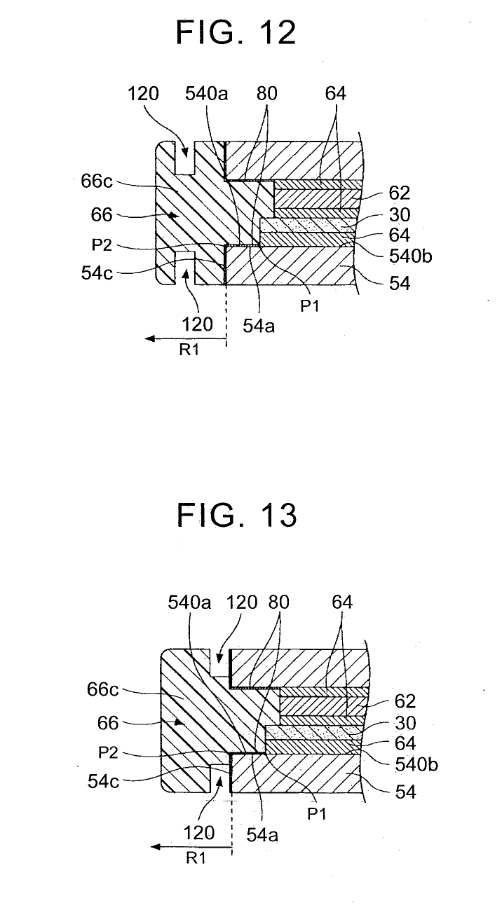

FIG. 12 is a cross-sectional view that shows the peel-off restraining part according to another embodiment (Embodiment 2) of the present invention.

The peel-off restraining part of the present embodiment is achieved by a groove part 120 formed in the heatsink-surrounding part 66c. The heatsink-surrounding part 66c corresponds to, as described above, an area on an outer side of the third heatsink 54 in the resin part 66 (see the arrow mark R1 of FIG. 12). The groove part 120 may be formed by a projection part or a bush of a mold that forms the resin part 66.

According to the present embodiment, since a volume of the heatsink-surrounding part 66c is reduced by an amount of the groove part 120, an expansion amount itself of the heatsink-surrounding part 66c during the moisture absorption is reduced. Thus, the downward load F (see FIG. 5) to the third heatsink 54, which acts due to the expansion of the heatsink-surrounding part 66c of the resin part 66, can be reduced. As a result, the tensile stress (see FIG. 6) is reduced, and the resin part 66 can be effectively restrained from being peeled from the resin close contact region 540a in the outer peripheral part of the third heatsink 54.

The groove part 120 is preferably formed over an entire circumference so as to surround the third heatsink 54 in the heatsink-surrounding part 66c. Alternatively, the groove part 120 may be formed partially not over an entire circumference. The cross-sectional shape of the groove part 120 is arbitrary and may be a triangular cross-section or the like without restricting to the rectangular cross-section as shown in the drawing. Further, a depth or a width (that is, a volume) of the groove part 120 is properly determined such that the load F (see FIG. 5) can be significantly reduced. The depth of the groove part 120 may be the same as, for example, the thickness of the third heatsink 54. The groove part 120 may be formed at an arbitrary position in the heatsink-surrounding part 66c in a lateral direction in a cross-sectional view of FIG. 12 but is preferably formed in the vicinity of the third heatsink 54. In this case, a magnitude of the load F (see FIG. 5) can be effectively reduced. In this point, ultimately, the groove part 120 may be formed adjacent to the side surface 54c of the third heatsink 54 as shown in FIG. 13. In this case, the depth of the groove part 120 is preferably set to be the thickness of the third heatsink 54 or less.

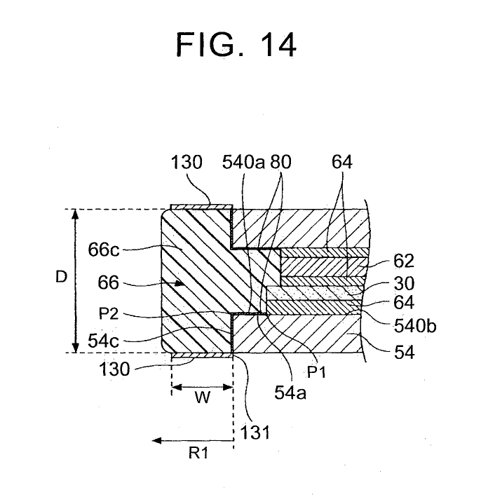

FIG. 14 is a cross-sectional view that shows a peel-off restraining part according to another embodiment (Embodiment 3) of the present invention.

The peel-off restraining part according to the present embodiment is achieved by a moisture-proof material coating layer 130 formed on a surface of the heatsink-surrounding part 66c. The moisture-proof material coating layer 130 may be formed by using an arbitrary moisture-proof material. The moisture-proof material may be, for example, a polyolefin-base resin, an acryl-base resin, or a silicone-base resin. Further, a coating method is arbitrary but a screen printing method, a dipping method, a spray method, a dispense method and the like can be used.

According to the present embodiment, a moisture absorption amount of the heatsink-surrounding part 66c is reduced due to the moisture-proof material coating layer 130 and an expansion amount of the heatsink-surrounding part 66c during the moisture absorption is reduced. Thus, the downward load F (see FIG. 5) to the third heatsink 54, which acts due to the expansion of the heatsink-surrounding part 66c of the resin part 66, can be reduced. As a result, the tensile stress (see FIG. 6) is reduced, and the resin part 66 can be effectively restrained from being peeled from the resin close contact region 540a in the outer peripheral part of the third heatsink 54.

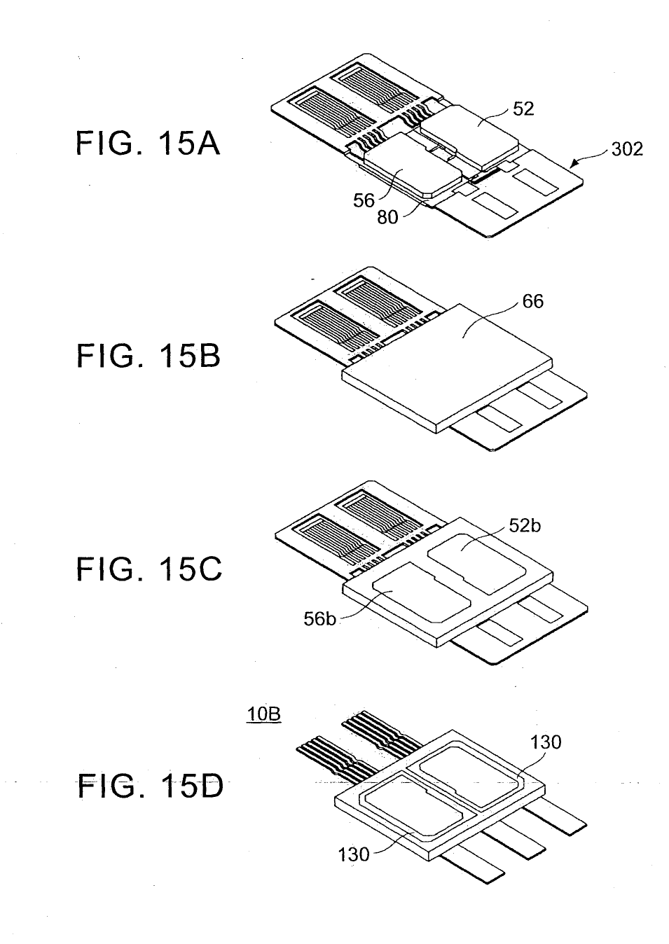

The moisture-proof material coating layer 130 is preferably formed over an entire circumference so as to surround the upper surface 54a of the third heatsink 54 in the heatsink-surrounding part 66c (see FIG. 15D) but may be formed only partially not over the entire circumference. A coating width W of the moisture-proof material coating layer 130 is properly determined such that the load F (see FIG. 5) can be significantly reduced. The coating width W of the moisture-proof material coating layer 130 is preferably set to a thickness D of the heatsink-surrounding part 66c or more (in the embodiment shown in the drawing, W<D). The coating width W is not necessarily constant over all circumference and may be properly set according to a width of an available region. Further, the moisture-proof material coating layer 130 may be formed additionally on the side surface of the heatsink-surrounding part 66c.

FIG. 15A to FIG. 15D are drawings that show an embodiment of a manufacturing method of a semiconductor device 10B that includes a peel-off restraining part according to Embodiment 3.

Firstly, the IGBT elements 20 and 30, the FWD elements 28 and 38, the respective terminals 60 and 62, and the second heatsink 52 and the fourth heatsink 56 are mounted on a lead frame 302 as shown in FIG. 15A, and the wire bonding is performed. Thereafter, also the primer is coated and the primer layer 80 is formed.

Next, the resin part 66 is formed by mold forming as shown in FIG. 15B.

Next, the respective upper parts of the resin part 66, the second heatsink 52, and the fourth heatsink 56 and the like are machined and the tie bar and the like are cut as shown in FIG. 15C.

Next, a moisture-proof material is coated on the resin part 66 to form the moisture-proof material coating layer 130 as shown in FIG. 15D, and a semiconductor device 10B is completed.

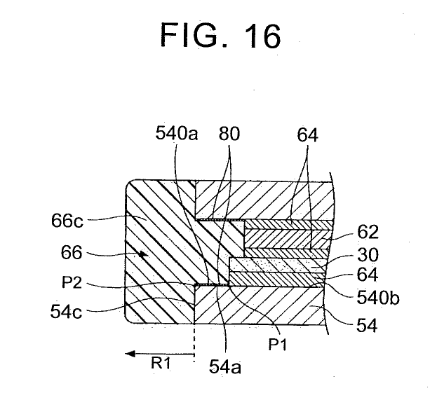

FIG. 16 is a cross-sectional view that shows a peel-off restraining part according to another embodiment (Embodiment 4) of the present invention.

The peel-off restraining part of the present embodiment is achieved by reducing an adhesive force between the side surface 54c of the third heatsink 54 and the heatsink-surrounding part 66c. A method of reducing the adhesive force may be a method in which the primer layer 80 is not formed on the side surface 54c of the third heatsink 54 (however, the primer layer 80 is formed on the upper surface 54a of the third heatsink 54) as shown in FIG. 16. Alternatively, the method of reducing the adhesive force may be a method in which a plating treatment that is applied on the upper surface 54a of the third heatsink 54 is not applied to the side surface 54c of the third heatsink 54, or a method in which a plating layer of the side surface 54c of the third heatsink 54 formed accompanying the plating treatment applied on the upper surface 54a of the third heatsink 54 is removed. For example, in the case in which a plating treatment applied on the upper surface 54a of the third heatsink 54 is a nickel plating treatment, the third heatsink 54 is formed of copper, and the primer layer 80 is formed of polyamide, even when the primer is coated on the side surface 54c of the third heatsink 54, reduction of the adhesive force can be achieved. This is because while the polyamide has high adhesiveness with nickel, it does not have high adhesiveness with copper. This is because the copper tends to grow an oxide film on a surface thereof, even when the primer is coated, it is broken by the oxide film, as a result, the adhesive strength between the primer layer 80 and the side surface 54c of the third heatsink 54 is degraded.

According to the present embodiment, since the adhesive force between the side surface 54c of the third heatsink 54 and the heatsink-surrounding part 66c is reduced, the downward load F (see FIG. 5) to the third heatsink 54, which acts due to the expansion of the heatsink-surrounding part 66c of the resin part 66 can be reduced. That is, the downward load F (see FIG. 5) transmitted via the close contact part between the heatsink-surrounding part 66c of the resin part 66 and the side surface 54c of the third heatsink 54 can be reduced. As a result, the tensile stress (see FIG. 6) is reduced and the resin part 66 can be effectively restrained from being peeled from the resin close contact region 540a in the outer peripheral part of the third heatsink 54.

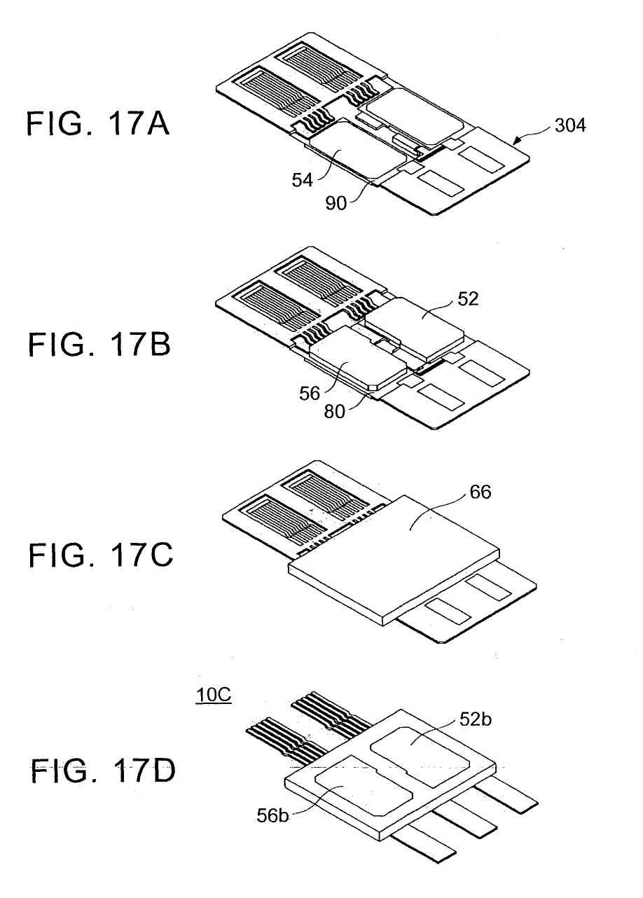

FIG. 17A to FIG. 17D are drawings that show an embodiment of a manufacturing method of a semiconductor device 10C that includes a peel-off restraining part according to Embodiment 4.

Firstly, a lead frame 304 is prepared as shown in FIG. 17A. The lead frame 304 is formed by applying a nickel plating treatment to a lead frame raw material (copper in the present embodiment), then, by applying press working. By applying the nickel plating treatment before the press working, the lead frame 304 that is not provided with a nickel plating layer 90 on a side surface can be formed. That is, the side surface of the lead frame 304 becomes an exposed state of copper. On the side surface of the lead frame 304, the oxide film grows as described above.

Then the IGBT elements 20 and 30, the FWD elements 28 and 38, the respective terminals 60 and 62, the second heatsink 52 and the fourth heatsink 56 are mounted on the lead frame 304 as shown in FIG. 17B and the wire bonding is performed. Thereafter, also the primer is coated to form the primer layer 80. At this time, the primer may be coated on the side surface of the lead frame 304 as well. For example, the primer is necessarily coated on the side surface of the lead frame 304 when the dipping method is used for coating.

Next, the mold forming is applied as shown in FIG. 17C to form the resin part 66. At this time, while the resin part 66 closely contacts also with the side surface of the lead frame 304 that does not include the nickel plating layer, as described above, due to the destruction by the oxide film, the adhesive force between the side surface 54c of the third heatsink 54 and the resin part 66 (the heatsink-surrounding part 66c) is reduced.

Then, the respective upper parts of the resin part 66, the second heatsink 52, and the fourth heatsink 56 are machined and the tie bars and the like are cut as shown in FIG. 17D, thus, the semiconductor device 10C is completed.

In the above, the respective embodiments have been described in detail. However, the present invention is not limited to particular embodiments and various modifications and alterations can be applied. Further, all or a plurality of the constituent elements of the embodiments described above can be combined.

For example, the peel-off restraining parts according to the respective embodiments described above may be combined in an arbitrary construction. For example, the peel-off restraining part according to the Embodiment 1 can be combined with any one, any arbitrary two, or all of the peel-off restraining parts according to the Embodiment 2, the peel-off restraining part according to the Embodiment 3 and the peel-off restraining part according to the Embodiment 4.

Further, the respective embodiments described above are formed to be a double-sided heat radiation configuration but may be formed to be a single-sided heat radiation configuration. That is, for example, a configuration in which the second heatsink 52, the fourth heatsink 56 and the respective terminals 60 and 62 are not present or a configuration in which the second heatsink 52 and the fourth heatsink 56 are provided in a form of a bus bar may be used. Also in this case, since the downward load F (see FIG. 5) is still applied, for example, the outer peripheral part of the third heatsink 54 during the moisture absorption, the peel-off restraining parts according to the respective embodiments described above can function effectively.

1. A semiconductor device comprising:
a metal member that has a surface that includes a semiconductor element mounting region and a resin close contact region, the resin close contact region extending from the semiconductor element mounting region to an outer peripheral edge of the metal member;
a semiconductor element mounted on the semiconductor element mounting region;
a resin part that extends to a position outside a side surface of the metal member, closely contacts with the resin close contact region, and collectively covers the semiconductor element and the metal member;
a primer layer disposed between the resin close contact region and the resin part; and
a peel-off restraining part configured to restrain the metal member and the resin part from peeling, due to moisture absorption of the resin part, from each other in an outer peripheral part of the resin close contact region.

2. The semiconductor device according to claim 1, wherein
the peel-off restraining part includes a groove part that is formed in the resin close contact region and located in a region of 3 mm or less from the outer peripheral edge of the surface of the metal member.

3. The semiconductor device according to claim 2, wherein
the primer layer is formed at a thickness of 0.1 μm or more in a region outside the groove part in the resin close contact region.

4. The semiconductor device according to claim 1, wherein
the peel-off restraining part includes a groove part that is formed in a part of the resin part outside the metal member.

5. The semiconductor device according to claim 1, wherein
the peel-off restraining part includes a moisture-proof material coating layer that is formed on a surface of a part of the resin part outside the metal member.

6. The semiconductor device according to claim 1, wherein
the peel-off restraining part includes an adhesive force reduction part configured to reduce an adhesive force between the resin part and the side surface of the metal member.

7. The semiconductor device according to claim 6, wherein
the adhesive force reduction part is achieved by not disposing the primer layer on the side surface of the metal member.

8. The semiconductor device according to claim 6, wherein
the adhesive force reduction part is achieved by not disposing a plating layer that is formed on the surface of the metal member on the side surface of the metal member.

9. A semiconductor device comprising:
a metal member that has a surface that includes a semiconductor element mounting region and a resin close contact region, the resin close contact region extending from the semiconductor element mounting region to an outer peripheral edge of the metal member;
a semiconductor element mounted on the semiconductor element mounting region;
a resin part that has moisture absorbency, extends to a position outside a side surface of the metal member, closely contacts with the resin close contact region, and collectively covers the semiconductor element and the metal member; and
a primer layer disposed between the resin close contact region and the resin part, wherein
a peel-off restraining part configured to restrain the metal member and the resin part from peeling from each other in an outer peripheral part of the resin close contact region is provided to at least one of the metal member and the resin part.

10. The semiconductor device according to claim 9, wherein
the peel-off restraining part includes a groove part that is formed in the resin close contact region and located in a region of 3 mm or less from the outer peripheral edge of the surface of the metal member.

11. The semiconductor device according to claim 9, wherein
the peel-off restraining part includes a groove part that is formed in a part of the resin part outside the metal member.

12. The semiconductor device according to claim 9,
wherein the peel-off restraining part includes the side surface exposed from the primer layer.

13. The semiconductor device according to claim 9, further comprising
a plating layer formed on the surface of the metal member, wherein
the peel-off restraining part includes the side surface of the metal member exposed from the plating layer.

14. A method of manufacturing a semiconductor device comprising steps of:
performing a plating treatment on a lead frame raw material;
forming a lead frame raw material that has a side surface exposed from a plating layer by performing a press working on the plated lead frame raw material;
mounting a semiconductor element on a surface of the press-worked lead frame raw material;
coating a primer on a surface and a side surface of the lead frame raw material on which the semiconductor element is mounted; and
collectively sealing the lead frame raw material and the semiconductor element with a resin by molding the resin after the coating of the primer so as to bring the resin into close contact with the surface and the side surface of the lead frame raw material.
